(19) United States
(12) Patent Application Publication
(10) Pub. No.: US 2024/0162176 A1
(43) Pub. Date: May 16, 2024

(54) SEMICONDUCTOR PACKAGE INCLUDING BUMP INTERCONNECTION STRUCTURE

(71) Applicant: SK hynix Inc., Icheon-si Gyeonggi-do (KR)

(72) Inventors: Kang Hun KIM, Icheon-si Gyeonggi-do (KR); Si Yun KIM, Icheon-si Gyeonggi-do (KR); Jun Yong SONG, Icheon-si Gyeonggi-do (KR)

(73) Assignee: SK hynix Inc., Icheon-si Gyeonggi-do (KR)

(21) Appl. No.: 18/308,891

(22) Filed: Apr. 28, 2023

(30) Foreign Application Priority Data
Nov. 10, 2022 (KR) 10-2022-0149834

(51) Int. Cl. H01L 23/00

(52) U.S. Cl. CPC H01L 24/05; H01L 24/13; H01L 24/16; H01L 2224/0401; H01L 2224/05557; H01L 2224/05582; H01L 2224/05624; H01L 2224/05647; H01L 2224/13082; H01L 2224/13147; H01L 2224/16145

(57) ABSTRACT

A semiconductor package includes a bump interconnection structure. The semiconductor package includes a first lead and a second lead spaced apart from each other on a first substrate, a bump disposed to face the first lead in a second substrate, and a solder layer configured to connect the bump and the first lead. The first lead has a stair shape that ascends toward the second lead.

### CROSS-REFERENCE TO RELATED APPLICATION

The present application claims priority under 35 U.S.C. § 119(a) to Korean application number 10-2022-0149834, filed in the Korean Intellectual Property Office on Nov. 10, 2022, the entire disclosure of which is incorporated herein by reference.

### BACKGROUND

The present disclosure relates to semiconductor technology, and particularly, to a semiconductor package including a bump interconnection structure.

As the electronic industry is rapidly developed, electronic products are further reduced in size and have been becoming multi-functioned as required by users. A semiconductor package that is used in electronic products has higher performance, higher integration, a higher speed, and a smaller size. The number of semiconductor chips or semiconductor dies that are embedded in the semiconductor package or the number of connection terminals or input/output (I/O) terminals required for a semiconductor device is increased. To form more connection terminals within a limited area, the density of the connection terminals or the I/O terminals is increased, and an isolation interval between the connection terminals or a pitch between the connection terminals is suddenly reduced. A bump interconnection structure using conductive bumps is applied to the connection terminals of the semiconductor package. As an isolation interval or pitch between the bumps is reduced, there is an increasing short risk between a bump and another bump adjacent to the bump.

### SUMMARY

In an embodiment, a semiconductor package may include a first lead and a second lead disposed to be spaced apart from each other on a first substrate, a bump disposed to face the first lead in a second substrate, and a solder layer configured to connect the bump and the first lead. The first lead may have a stair shape that ascends toward the second lead.

In an embodiment, a semiconductor package may include a first lead and a second lead disposed to be spaced apart from each other on a first substrate, through vias connected to the first and second leads, respectively, and extended to penetrate the first substrate, a first bump disposed to face the first lead in a second substrate, and a solder layer configured to connect the first bump and the first lead. The first lead may have a stair shape that ascends toward the second lead.

### BRIEF DESCRIPTION OF THE DRAWINGS

FIG. 1 is a cross-sectional view illustrating a semiconductor package according to an embodiment.

FIG. 2 is a cross-sectional view illustrating that a lead of the semiconductor package in FIG. 1 has been enlarged.

FIG. 3 is a cross-sectional view illustrating a semiconductor package according to an embodiment.

FIGS. 4 and 5 are cross-sectional views illustrating leads of semiconductor packages according to an embodiment.

FIG. 6 is a cross-sectional view illustrating a semiconductor package according to an embodiment.

FIG. 7 is a block diagram illustrating an electronic system using a memory card including a semiconductor package according to an embodiment; and

FIG. 8 is a block diagram illustrating an electronic system including a semiconductor package according to an embodiment.

### DETAILED DESCRIPTION

Terms that are used in the description of examples of this application are terms selected by taking into consideration functions in proposed embodiments, and the meanings of the terms may be different depending on a user, an operator's intention or practice in the technical field. The meaning of a term used follows the definition of the term if the term has been specifically defined in this specification, and may be interpreted as a meaning which may be commonly recognized by those skilled in the art if the term has not been specifically defined in this specification.

In the description of examples of this application, terms, such as a “first”, a “second”, a “side”, a “top”, and a “bottom or lower”, are used to distinguish between members and are not used to limit the members themselves or to mean a specific order.

A semiconductor substrate may denote a semiconductor wafer on which electronic parts and elements are integrated. Integrated circuits may be integrated on the semiconductor substrate. The semiconductor substrate may be diced into a plurality of semiconductor chips or a plurality of semiconductor dies.

The semiconductor chip may be a memory chip on which memory, such DRAM, SRAM, NAND flash memory, NOR flash memory, MRAM, ReRAM, FeRAM, or PcRAM, has been integrated. The semiconductor chip may denote a logic die or an ASIC chip, an application processor (AP), a graphic processing unit (GPU), a central processing unit (CPU), or a system on chip (SoC) in which logic circuits have been integrated on a semiconductor substrate.

The semiconductor chip may be a component that constitutes a semiconductor package or a semiconductor product. The semiconductor chip may be applied to information communication devices such as a mobile terminal, bio or health care-related electronic devices, and electronic devices wearable by human beings. The semiconductor chip may be applied to Internet of Things.

In the entire specification, the same reference numerals may denote the same components. Accordingly, the same reference numerals or similar reference numerals may be described with reference to other drawings although they are not mentioned or described in corresponding drawings. Furthermore, although reference numerals are not shown, they may be described with reference to other drawings.

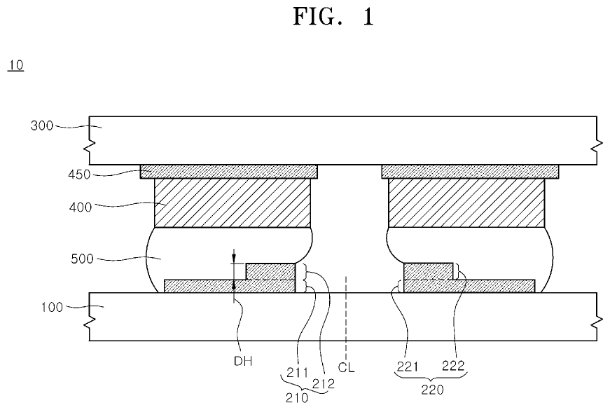

FIG. 1 is a cross-sectional view illustrating a semiconductor package 10 according to an embodiment.

Referring to FIG. 1, the semiconductor package 10 may include a first substrate 100 and a second substrate 300, and may be constructed to include a first lead 210, a second lead 220, bumps 400, and solder layers 500. The first lead 210, the second lead 220, the bumps 400, and the solder layers 500 may form bump interconnection structures. The bump interconnection structures may be elements that electrically connect the first substrate 100 and the second substrate 300.

The first lead 210 and the second lead 220 may be disposed on the first substrate 100. The first lead 210 and the second lead 220 may be disposed to face the second substrate 300 on the first substrate 100. The first lead 210 and the second lead 220 may be disposed on both sides of a center line CL that is set in the first substrate 100 with the center line CL interposed between the first lead 210 and the second lead 220. The first lead 210 and the second lead 220 may be disposed to be spaced apart from each other in a direction transverse to the first substrate 100. The first lead 210 and the second lead 220 may be elements to which the bumps 400 are connected, respectively, and may be bump lands or conductive pads on which the bumps 400 are landed, respectively. Each of the first lead 210 and the second lead 220 may be some parts of conductive traces that are formed in the first substrate 100. The first lead 210 and the second lead 220 may be formed to include a metal layer.

The bumps 400 may be disposed in the second substrate 300. The bumps 400 may be formed in shapes that protrude from the second substrate 300 so that the bumps 400 are directed toward the first substrate 100. The bumps 400 may be disposed to face the first lead 210 and the second lead 220, respectively. The bumps 400 may be disposed at locations that overlap the first lead 210 and the second lead 220, respectively. The bumps 400 may include a conductive material, for example, a metal material such as copper (Cu). Conductive pads 450 to which the bumps 400 are connected or coupled may be formed between the respective bumps 400 and the second substrate 300. The conductive pads 450 may be formed to include a metal material, such as copper (Cu) or aluminum (Al).

The solder layer 500 that connects the bump 400 and the first lead 210 may be formed between the bump 400 and the first lead 210. Another solder layer 500 that connects another bump 400 adjacent to the bump 400 and the second lead 220 may be formed between the adjacent bump 400 and the second lead 220. The solder layer 500 may include a soldering material, such as tin (Sn). As the solder layer 500 connects the bump 400 and the first lead 210, the bump 400 may be bonded to the first lead 210.

The first lead 210 may be formed to have a stair shape that ascends toward the second lead 220. The second lead 220 may be formed to have a stair shape that ascends toward the first lead 210. The first lead 210 and the second lead 220 may be formed to have a mirror image shape with the center line CL interposed between the first lead 210 and the second lead 220.

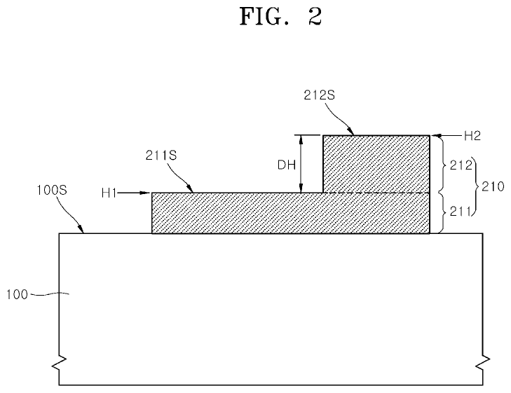

FIG. 2 is a cross-sectional view illustrating that the first lead 210 of the semiconductor package 10 in FIG. 1 has been enlarged.

Referring to FIG. 2, the first lead 210 that is disposed on a surface 100S of the first substrate 100 may be constructed to include a first part 211 of the first lead and a second part 212 of the first lead. As the first part 211 of the first lead and the second part 212 of the first lead have a surface height difference DH, the first lead 210 may have a cross-sectional shape of a stair shape. The first part 211 of the first lead may be a part of the first lead 210 that is formed on the surface 100S of the first substrate 100. The second part 212 of the first lead may be another part of the first lead 210 that is disposed on the first part 211 of the first lead. The first part 211 of the first lead and the second part 212 of the first lead may be some parts that constitute one body.

The second part 212 of the first lead may include a part that exposes some part of the first part 211 of the first lead and that protrudes upward from the first part 211 of the first lead. The second part 212 of the first lead may include a part that protrudes from the first part 211 of the first lead to the second substrate (300 in FIG. 1). The second part 212 of the first lead may be a part the surface height of which from the first substrate 100 is higher than the exposed part of the first part 211 of the first lead. A surface height H2 of a surface 212S of the second part 212 of the first lead may be higher than a surface height H1 of an exposed surface 211S of the first part 211 of the first lead.

The stair shape of the first lead 210 may be formed by forming a metal layer to a total thickness of the second part 212 of the first lead and the first part 211 of the first lead and recessing some part of the metal layer or removing some part of the metal layer through selective etching.

Referring to FIG. 1, the second part 212 of the first lead may be placed closer to the second lead 220 than the exposed part of the first part 211 of the first lead. The second lead 220 may be constructed to include a first part 221 of the second lead and a second part 222 of the second lead. The second part 222 of the second lead may include a part that exposes some part of the first part 221 of the second lead and that protrudes from the first part 221 of the second lead to the second substrate 300. The second part 222 of the second lead may be a part the surface height of which from the first substrate 100 is higher than the exposed part of the first part 221 of the second lead. The second part 222 of the second lead may be placed closer to the first lead 210 than the exposed part of the first part 221 of the second lead. The second lead 220 may be disposed to face the first lead 210 so that the second part 222 of the second lead faces the second part 212 of the first lead.

Referring to FIG. 1, the first substrate 100 may include a semiconductor substrate in which integrated circuit elements have been integrated. The second substrate 300 may also include a semiconductor substrate in which integrated circuit elements have been integrated. The first substrate 100 may have a form of a semiconductor chip, a semiconductor die, or a wafer. The second substrate 300 may have a form of a semiconductor chip, a semiconductor die, or a wafer.

The integrated circuit element may include volatile memory e, such as dynamic random-access memory (DRAM), or nonvolatile memory, such as NAND flash memory. The semiconductor substrate may be a substrate including silicon (Si) or germanium (Ge), or may be a substrate including silicon carbide (SiC), gallium arsenide (GaAs), indium arsenide (InAs), or indium phosphorous (InP).

The first substrate 100 may include an interconnection component on which semiconductor devices, electronic devices, or the second substrate 300 is mounted. The interconnection component may include a printed circuit board (PCB) or an interposer.

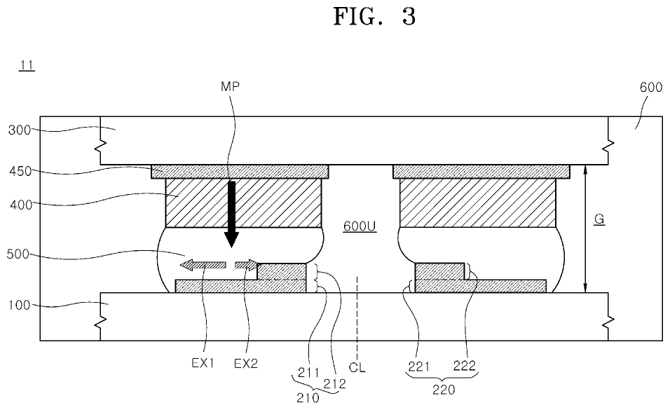

FIG. 3 is a cross-sectional view illustrating a semiconductor package 11 according to an embodiment. The semiconductor package 11 in FIG. 3 may have a structure which further includes an encapsulant layer 600 in the structure of the semiconductor package 10 in FIG. 1. In FIG. 3, the same reference numeral as that in FIG. 1 may indicate the same element.

Referring to FIG. 3, the semiconductor package 11 may include a first substrate 100 and a second substrate 300, and may be constructed to include a first lead 210, a second lead 220, bumps 400, and solder layers 500. The semiconductor package 11 may include a structure in which the second substrate 300 is mounted on the first substrate 100 and the bump 400 is bonded to the first lead 210 by the solder layer 500. The semiconductor package 11 may further include the encapsulant layer 600. The encapsulant layer 600 may be formed to include an encapsulation material, such as an epoxy molding compound (EMC).

The encapsulant layer 600 may be formed to encapsulate the second substrate 300 by covering the second substrate 300. The second substrate 300 may have a chip or die shape that has been diced from a wafer. The encapsulant layer 600 may be formed to protect the second substrate 300 by covering the second substrate 300. The encapsulant layer 600 may be formed by a molding process using an encapsulation material. The encapsulant layer 600 may be formed to extend between the second substrate 300 and the first substrate 100.

The encapsulant layer 600 may be formed so that some encapsulation materials of the encapsulant layer 600 are introduced into a gap G between the second substrate 300 and the first substrate 100 and extended part 600U of the encapsulant layer 600 extends to fill the gap G between the second substrate 300 and the first substrate 100. The encapsulant layer 600 may be formed by a molded underfill (MUF) process. As the extended part 600U of the encapsulant layer 600 expands into the gap G between the second substrate 300 and the first substrate 100, the extended part 600U of the encapsulant layer 600 may surround and encapsulate a bump interconnection structure that includes the bump 400, the first lead 210, and the solder layer 500. The extended part 600U of the encapsulant layer 600 may electrically isolate the first lead 210 and the second lead 220 by filling a gap between the first lead 210 and the second lead 220. The extended part 600U of the encapsulant layer 600 may fill the gap G between the second substrate 300 and the first substrate 100 so that the extended part 600U electrically isolates the bumps 400 that are adjacent to each other and isolates the solder layers 500 that are adjacent to each other.

When the MUF process of forming the encapsulant layer 600 is performed, molding pressure MP at which the encapsulant layer 600 is molded may be applied to the second substrate 300, the bump 400, the solder layer 500, etc. The solder layer 500 may be made of a solder material containing tin (Sn). Because the solder material has relatively smaller stiffness than copper (Cu) that forms the bump 400, the solder layer 500 is likely to be deformed by the molding pressure MP. If the molding pressure MP is applied to the solder layer 500 in a direction perpendicular to the second substrate 300 or the first substrate 100, a deformation phenomenon in which the solder material of the solder layer 500 extrudes to both sides by the molding pressure MP may occur.

In the solder layer 500 bonded to the first lead 210, there may be a risk that the solder material of the solder layer 500 will extrude in a first extrusion direction EX1 opposite to the second lead 220 and second extrusion direction EX2 toward the second lead 220. The second part 212 of the first lead may have a shape that further protrudes from the first part 211 of the first lead toward the second substrate 300, so that the second part 212 of the first lead may act as a barrier or threshold that suppresses the extrusion of the solder material in the second extrusion direction EX2.

By the extrusion suppression action or extrusion obstruction action of the second part 212 of the first lead, the extrusion of the solder material of the solder layer 500 may be induced to be relatively more dominant in the first extrusion direction EX1 toward a direction opposite to the second lead 220 than in the second extrusion direction EX2 toward the second lead 220. The extrusion of the solder material of the solder layer 500, which is caused by the molding pressure MP, may be relatively suppressed and reduced in the second extrusion direction EX2 toward the second lead 220. The extrusion of the solder material from the solder layer 500 may cause a failure in which two adjacent solder layers 500 are interconnected and electrically shorted. Because the extrusion of the solder material from the solder layer 500 to the second lead 220 is reduced and suppressed by the second part 212 of the first lead, the occurrence of an unwanted electrical short can be suppressed or reduced.

Even in an adjacent solder layer 500 that has been bonded to the second lead 220, the extrusion of the solder material in the first lead 210 can be suppressed, limited, or reduced by the second part 222 of the second lead. Accordingly, the occurrence of an unwanted electrical short attributable to the extrusion of a solder can be suppressed or reduced.

Referring to FIG. 1, when the second substrate 300 is mounted on the first substrate 100 and the bumps 400 are bonded to the first and second leads 210 and 220 by the solder layers 500, respectively, the second part 212 of the first lead and the second part 222 of the second lead may act to suppress the extrusion of the solder material from the solder layers 500 or may act to hinder the extrusion of the solder material from the solder layers 500. The second part 212 of the first lead and the second part 222 of the second lead can suppress or hinder the solder material from extruding into a part between the first lead 210 and the second lead 220. Accordingly, the second part 212 of the first lead and the second part 222 of the second lead can suppress the first lead 210 and the second lead 220 from being electrically shorted due to the solder material that has excessively extruded, or the second part 212 of the first lead and the second part 222 of the second lead can reduce an electrical short between the first lead 210 and the second lead 220 attributable to the solder material that has excessively extruded.

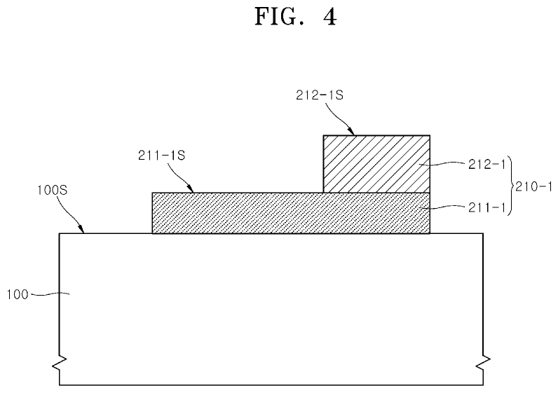

FIG. 4 is a cross-sectional view illustrating a first lead 210-1 of the semiconductor package 10 in FIG. 1 according to an embodiment.

Referring to FIGS. 1 and 4, the first lead 210 of the semiconductor package 10 in FIG. 1 may be formed in a shape of the first lead 210-1 that is presented in FIG. 4. The first lead 210-1 may be constructed to include a first lead layer 211-1 on the lower side of the first lead 210-1 and a second lead layer 212-1 on the upper side of the first lead 210-1. The first lead layer 211-1 and the second lead layer 212-1 may be formed to form a stair shape. The first lead layer 211-1 may be formed on a surface 100S of a first substrate 100. The second lead layer 212-1 may be formed on the first lead layer 211-1. The second lead layer 212-1 may be formed on the first lead layer 211-1 while exposing some part of the first lead layer 211-1. A surface 212-1S of the second lead layer 212-1 may be placed at a higher location than a surface 211-1S of an exposed part of the first lead layer 211-1. As described above, the first lead 210-1 may be formed as a multi-layer structure in which the first and second lead layers 211-1 and 212-1 form the stair shape.

The second lead layer 212-1 may be placed closer to the second lead 220 than the exposed part of the first lead layer 211-1. The second lead layer 212-1 may act as a barrier or threshold that suppresses or hinders the extrusion of the solder material of the solder layer 500 like the second part 212 of the first lead in FIG. 1.

The second lead layer 212-1 may be formed to include a metal layer different from that of the first lead layer 211-1. The first lead layer 211-1 may include a metal layer that is better than that of the second lead layer 212-1 in forming an intermetallic compound (IMC) along with a solder material of the solder layer 500. The second lead layer 212-1 may include another metal layer that is poorer than that of the first lead layer 211-1 in forming an IMC along with a solder material of the solder layer 500. For example, the second lead layer 212-1 may be formed to include a nickel (Ni) layer. The first lead layer 211-1 may be formed to include a copper (Cu) layer. The Ni layer may have a relatively poorer degree to which an IMC is formed along with tin (Sn) included in a solder material than the Cu layer. As described above, if it is relatively difficult for the second lead layer 212-1 to form an IMC with a solder material of the solder layer 500, this may help an action of the second lead layer 212-1 suppressing the extrusion of a solder material of the solder layer 500 or an action of the second lead layer 212-1 hindering the extrusion of the solder material of the solder layer 500.

FIG. 5 is a cross-sectional view illustrating a first lead 210-2 of the semiconductor package 10 in FIG. 1 according to an embodiment.

Referring to FIGS. 1 and 5, the first lead 210 of the semiconductor package 10 in FIG. 1 may be formed in a shape of the first lead 210-2 presented in FIG. 5. The first lead 210-2 may be constructed to include a first lead layer 211-2 on the lower side of the first lead 210-2 and a second lead layer 212-2 on the upper side of the first lead 210-2. The first lead 210-2 may further include a supporting insulating layer 213-2. The supporting insulating layer 213-2 may be formed between the second lead layer 212-2 and the first substrate 100 while supporting the second lead layer 212-2. The supporting insulating layer 213-2 may be formed in parallel to the first lead layer 211-2 next to the first lead layer 211-2. As the second lead layer 212-2 is supported by the supporting insulating layer 213-2, the first lead layer 211-2 and the second lead layer 212-2 may be formed to form a stair shape. The first lead layer 211-2 may be formed on a surface 100S of the first substrate 100. A surface 212-2S of the second lead layer 212-2 may be placed at a higher location than a surface 211-2S of the first lead layer 211-2.

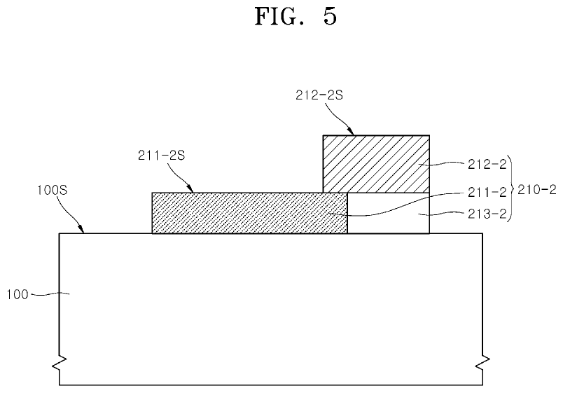

FIG. 6 is a cross-sectional view illustrating a semiconductor package 12 according to an embodiment.

Referring to FIG. 6, the semiconductor package 12 may include a first substrate 2100 and a second substrate 2300, and may be constructed to include through vias 2190, a first lead 2210, a second lead 2220, first bumps 2400, second bumps 2401, solder layers 2500, and an encapsulant layer 2600. The first lead 2210, the second lead 2220, the first bumps 2400, and the solder layers 500 may form bump interconnection structures. The bump interconnection structures may be elements that electrically connect the first substrate 2100 and the second substrate 2300.

The first lead 2210 and the second lead 2220 may be disposed on the first substrate 2100. The through vias 2190 may be elements that are connected to the first and second leads, respectively, and that are extended to penetrate the first substrate 2100. The through vias 2190 may be perpendicular connection elements that penetrate the first substrate 2100. The through via 2190 may be formed in the form of a through silicon via (TSV). The second bumps 2401 may be formed as elements that have substantially the same forms as the first bumps 2400. The second bumps 2401 may be formed to be connected to the through vias 2190, respectively. Second conductive pads 2451 may be formed between the through vias 2190 and the second bumps 2401, respectively.

The first lead 2210 and the second lead 2220 may be disposed to face each other on both sides of a center line CL set in the first substrate 2100 with the center line CL interposed between the first lead 2210 and the second lead 2220. The first lead 2210 and the second lead 2220 may be disposed on a side opposite to the side of the first substrate 2100 with respect to the second bumps 2401 with the first substrate 2100 interposed between the first lead 2210 and the second lead 2220. The second bumps 2401 may be front bumps. The first lead 2210 and the second lead 2220 may be formed as back bumps opposite to the front bumps. The first lead 2210 and the second lead 2220 may be electrically connected to the second bumps 2401 on the opposite side by the through vias 2190, and may be connected to the second bumps 2401 in a signal manner.

FIG. 6 shows that the through vias 2190 have been introduced into the first substrate 2100. Although not illustrated, other through vias may be introduced to penetrate the second substrate 2300. The other through vias that substantially penetrate the second substrate 2300 may be formed as perpendicular connection elements that are connected to the first bumps 2400, respectively. First conductive pads 2450 may be formed between the first bumps 2400 and the second substrate 2300.

The solder layer 2500 that connects the first bump 2400 and the first lead 2210 may be formed between the first bump 2400 and the first lead 2210. Another solder layer 2500 that connects another first bump 2400 adjacent to the first bump 2400 and the second lead 2220 may be formed between the adjacent first bump 2400 and the second lead 2220. The first lead 2210 may be formed to have a stair shape that ascends toward the second lead 2220. The second lead 2220 may be formed to have a stair shape that ascends toward the first lead 2210.

The first lead 2210 that is disposed on a surface of the first substrate 2100 may be constructed to include a first part 2211 of the first lead and a second part 2212 of the first lead. Because the first part 2211 of the first lead and the second part 2212 of the first lead have a surface height difference, the first lead 2210 may have a cross-sectional shape of a stair shape. The second part 2212 of the first lead may include a part that exposes some part of the first part 2211 of the first lead and that protrudes from the first part 2211 of the first lead toward the second substrate 2300. The second part 2212 of the first lead may be placed closer to the second lead 2220 than the part of the first part 2211 of the first lead, which has been exposed by the second part 2212 of the first lead. The second lead 2220 may be constructed to include a first part 2221 of the second lead and a second part 2222 of the second lead.

The encapsulant layer 2600 of the semiconductor package 12 may be formed to encapsulate the second substrate 2300 by covering the second substrate 2300. The encapsulant layer 2600 may be molded to have a shape that exposes an upper surface 2300BS of the second substrate 2300. The upper surface 2300BS of the second substrate 2300 may be exposed to the outside of the encapsulant layer 2600, thereby helping heat dissipation of the semiconductor package 12. The encapsulant layer 2600 may be extended so that some encapsulation materials of the encapsulant layer 2600 are introduced into a gap G between the second substrate 2300 and the first substrate 2100 and some part of the encapsulant layer 2600 fills the gap G between the second substrate 2300 and the first substrate 2100. The extended some part of the encapsulant layer 2600 may encapsulate a bump interconnection structure including the first bump 2400, the first lead 2210, and the solder layer 2500 by surrounding the bump interconnection structure.

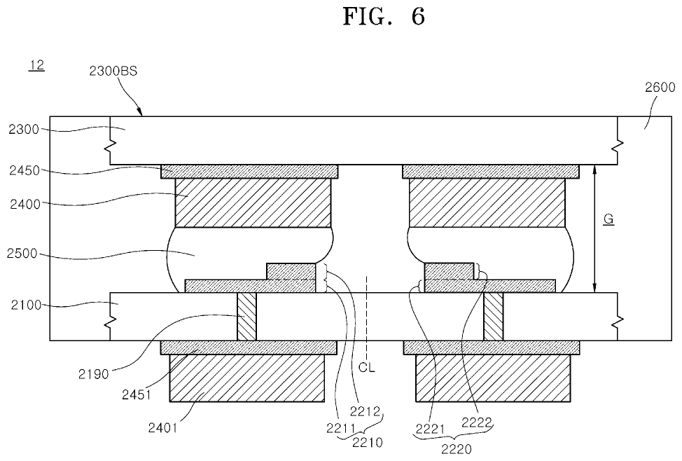

FIG. 7 is a block diagram illustrating an electronic system including a memory card 7800 employing at least one semiconductor package according to an embodiment of the present disclosure. The memory card 7800 includes memory 7810 and a memory controller 7820. In an embodiment, the memory 7810 represents a nonvolatile memory device. The memory 7810 and the memory controller 7820 may store data or read out the stored data. At least one of the memory 7810 and the memory controller 7820 may include at least one semiconductor package according to an embodiment of the present disclosure. The memory controller 7820 may control the memory 7810 such that stored data is read out of or data is stored in the memory 7810 in response to a read/write request from a host 7830.

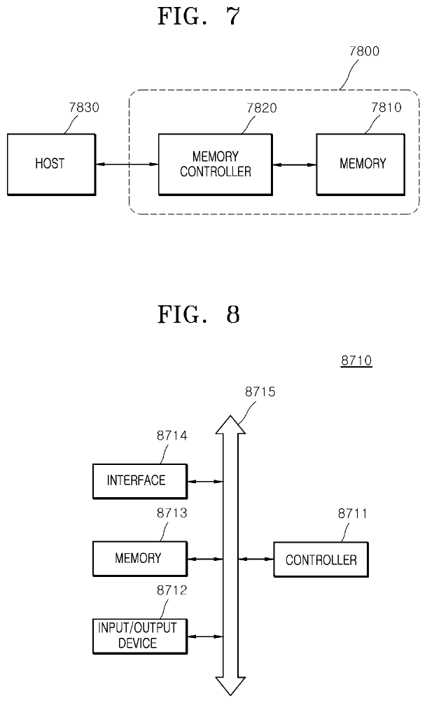

FIG. 8 is a block diagram illustrating an electronic system 8710 including at least one semiconductor package according to an embodiment of the present disclosure. The electronic system 8710 may include a controller 8711, an input/output device 8712, and memory 8713. The controller 8711, the input/output device 8712, and the memory 8713 may be coupled with one another through a bus 8715 providing a path through which data move.

In an embodiment, the controller 8711 may include one or more microprocessor, digital signal processor, microcontroller, and/or logic device capable of performing the same functions as these components. The controller 8711 and/or the memory 8713 may include at least one semiconductor package according to an embodiment of the present disclosure. The input/output device 8712 may include at least one selected among a keypad, a keyboard, a display device, a touch screen and so forth. The memory 8713 may be a device for storing data. The memory 8713 may store data and/or commands to be executed by the controller 8711, and the like.

The memory 8713 may include volatile memory such as a DRAM and/or a nonvolatile memory such as a flash memory. For example, flash memory may be mounted to an information processing system such as a mobile terminal or a desktop computer. The flash memory may constitute a solid-state disk (SSD). In this case, the electronic system 8710 may stably store a large amount of data in a flash memory system.

The electronic system 8710 may further include an interface 8714 configured to transmit and receive data to and from a communication network. The interface 8714 may be a wired or wireless type. For example, the interface 8714 may include an antenna or a wired or wireless transceiver.

The electronic system 8710 may be realized as a mobile system, a personal computer, an industrial computer, or a logic system performing various functions. For example, the mobile system may be any one of a personal digital assistant (PDA), a portable computer, a tablet computer, a mobile phone, a smart phone, a wireless phone, a laptop computer, a memory card, a digital music system and an information transmission/reception system.

If the electronic system 8710 represents equipment capable of performing wireless communication, the electronic system 8710 may be used in a communication system using a technique of code division multiple access (CDMA), global system for mobile communications (GSM), North American digital cellular (NADC), enhanced-time division multiple access (E-TDMA), wideband code division multiple access (WCDMA), CDMA2000, long term evolution (LTE), or wireless broadband Internet (WiBro).

The embodiments of the present disclosure have been described so far. A person having ordinary knowledge in the art to which the present invention pertains will understand that the present invention may be implemented in a modified form without departing from an intrinsic characteristic of the present disclosure. Accordingly, the disclosed embodiments should be considered from a descriptive viewpoint, not from a limitative viewpoint. The range of the present disclosure is described in the claims not the aforementioned description, and all differences within an equivalent range thereof should be construed as being included in the present disclosure.

What is claimed is:

1. A semiconductor package comprising:
a first lead and a second lead spaced apart from each other on a first substrate;
a bump disposed to face the first lead in a second substrate; and
a solder layer configured to connect the bump and the first lead,
wherein the first lead has a stair shape that ascends toward the second lead.

2. The semiconductor package of claim 1, wherein:
the first lead comprises a first part and a second part,
the second part of the first lead leaves a part of the first part of the first lead exposed, and
the second part of the first lead has a higher surface height from the first substrate toward the second substrate than the exposed part of the first part of the first lead.

3. The semiconductor package of claim 2, wherein the second part of the first lead protrudes from the first part of the first lead toward the second substrate.

4. The semiconductor package of claim 2, wherein the second part of the first lead is closer to the second lead than the exposed part of the first part of the first lead.

5. The semiconductor package of claim 1, wherein the second lead has a stair shape that ascends toward the first lead.

6. The semiconductor package of claim 1, further comprising an encapsulant layer that extends between the second substrate and the first substrate while covering the second substrate and that surrounds the bump, the first lead, and the solder layer.

7. The semiconductor package of claim 1, wherein the first lead comprises:
a first lead layer; and
a second lead layer formed on the first lead layer while leaving a part of the first lead layer exposed.

8. The semiconductor package of claim 7, wherein the second lead layer is placed closer to the second lead than the exposed part of the first lead layer.

9. The semiconductor package of claim 7, wherein the second lead layer comprises a metal layer different from a metal layer of the first lead layer.

10. The semiconductor package of claim 7, wherein the first lead further comprises a supporting insulating layer formed between the second lead layer and the first substrate while supporting the second lead layer.

11. A semiconductor package comprising:
a first lead and a second lead spaced apart from each other on a first substrate;
first and second through vias connected to the first and second leads, respectively, the first and second through vias penetrating the first substrate;
a first bump disposed to face the first lead from a second substrate; and
a solder layer configured to connect the first bump and the first lead,
wherein the first lead has a stair shape that ascends toward the second lead.

12. The semiconductor package of claim 11, wherein:
the first lead comprises a first part and a second part,
the second part of the first lead leaves a part of the first part of the first lead exposed, and
the second part of the first lead has a higher surface height from the first substrate toward the second substrate than the exposed part of the first part of the first lead.

13. The semiconductor package of claim 12, wherein the second part of the first lead protrudes from the first part of the first lead toward the second substrate.

14. The semiconductor package of claim 12, wherein the second part of the first lead is closer to the second lead than the exposed part of the first part of the first lead.

15. The semiconductor package of claim 11, further comprising an encapsulant layer that extends between the second substrate and the first substrate while covering the second substrate and that surrounds the first bump, the first lead, and the solder layer.

16. The semiconductor package of claim 11, wherein the first lead comprises:
a first lead layer; and
a second lead layer formed on the first lead layer while leaving a part of the first lead layer exposed.

17. The semiconductor package of claim 16, wherein the second lead layer is placed closer to the second lead than the exposed part of the first lead layer.

18. The semiconductor package of claim 16, wherein the second lead layer comprises a metal layer different from a metal layer of the first lead layer.

19. The semiconductor package of claim 16, wherein the first lead further comprises a supporting insulating layer formed between the second lead layer and the first substrate while supporting the second lead layer.

20. The semiconductor package of claim 11, further comprising a second bump connected to the first through via, the second bump being located on the opposite side of the first substrate from the first lead.
